(19) United States
(12) Patent Application Publication
(10) Pub. No.: US 2024/0260397 A1
(43) Pub. Date: Aug. 1, 2024

(54) DISPLAY PANEL AND DISPLAY APPARATUS

(71) Applicant: Visionox Technology Inc., Suzhou (CN)

(72) Inventors: Haohan ZHANG, Suzhou (CN); Yiming XIAO, Suzhou (CN); Yuan YAO, Suzhou (CN); Bowen YANG, Suzhou (CN); Xuejing ZHU, Suzhou (CN); Liusong NI, Suzhou (CN)

(73) Assignee: Visionox Technology Inc., Suzhou (CN)

(21) Appl. No.: 18/629,190

(22) Filed: Apr. 8, 2024

Related U.S. Application Data
(63) Continuation of application No. PCT/CN2023/110317, filed on Jul. 31, 2023.

(30) Foreign Application Priority Data
Aug. 2, 2022 (CN) 202210925417.3

(51) Int. Cl. H10K 59/80; H10K 59/122; H10K 59/131

(52) U.S. Cl. CPC H10K 59/8722; H10K 59/122; H10K 59/131; H10K 59/8723; H10K 59/873

(57) ABSTRACT

A display panel and a display apparatus. The display panel includes a display area and a frame area surrounding the display area, and the display panel includes: a base plate; and an isolation portion disposed on the base plate and located in the frame area, where the isolation portion includes a first segment and a second segment located on a side of the first segment facing the base plate, and an orthographic projection area of the first segment on the base plate is greater than that of the second segment on the base plate.

### CROSS-REFERENCE TO RELATED APPLICATIONS

The present application is a continuation of International Application No. PCT/CN2023/110317, which is filed on Jul. 31, 2023, and claims priority to Chinese Patent Application No. 202210925417.3, entitled “DISPLAY PANEL, DISPLAY APPARATUS, AND METHOD FOR PREPARING DISPLAY PANEL” and filed on Aug. 2, 2022, both of which are incorporated herein by reference in their entireties.

### TECHNICAL FIELD

The present application relates to the field of display, and specifically relates to a display panel and a display apparatus.

### BACKGROUND

Flat display panels such as liquid crystal display (LCD) panels, organic light emitting display (OLED) panels, and display panels using light emitting diode (LED) devices have been widely used in various consumer electronics such as mobile phones, televisions, personal digital assistants, digital cameras, notebook computers, and desktop computers due to their advantages of high image quality, power saving, thin body, wide application range, etc., and have become the mainstream in display apparatuses.

OLED panels emit light by use of organic light emitting materials, the organic light emitting materials are particularly sensitive to water and oxygen, and water absorbing expansion of the materials and thus peeling of film layers may occur due to invasion of water and oxygen, thereby leading to problems such as poor sealing.

### SUMMARY

Embodiments of the present application provide a display panel, a display apparatus, and a method for preparing the display panel, which aim to improve the sealing performance of the display panel.

An embodiment of a first aspect of the present application provides a display panel, the display panel includes a display area and a frame area surrounding the display area, where the display panel includes a base plate; and an isolation portion disposed on the base plate and located in the frame area, where the isolation portion comprises a first segment and a second segment located on a side of the first segment facing the base plate, and an orthographic projection area of the first segment on the base plate is greater than that of the second segment on the base plate.

According to implementations of the first aspect of the present application, the isolation portion is disposed surrounding the display area to form an enclosed construction shaped in a ring.

According to any of the foregoing implementations of the first aspect of the present application, two or more isolation portions are provided, and the two or more isolation portions are spaced apart from each other in a direction away from the display area.

According to any of the foregoing implementations of the first aspect of the present application, the isolation portion further includes a third segment located on a side of the second segment facing the base plate, and an orthographic projection area of the third segment on the base plate is greater than that of the second segment on the base plate.

According to any of the foregoing implementations of the first aspect of the present application, the display panel further includes a pixel definition layer disposed on the base plate, where the pixel definition layer includes a plurality of pixel definition portions located in the display area and a plurality of pixel openings enclosed by the pixel definition portions, and the third segment and the pixel definition portions are formed in a same layer with a same material.

According to any of the foregoing implementations of the first aspect of the present application, the pixel definition layer further includes through holes penetrating through the pixel definition layer, and the through holes are located in the frame area.

According to any of the foregoing implementations of the first aspect of the present application, a plurality of through holes are spaced apart from each other in the frame area.

According to any of the foregoing implementations of the first aspect of the present application, at least a part of the pixel definition layer located between adjacent two through holes is further used as the third segment.

According to any of the foregoing implementations of the first aspect of the present application, the material of the pixel definition layer includes an inorganic material.

According to any of the foregoing implementations of the first aspect of the present application, the display panel further includes a spacer portion located on a side of the pixel definition portion away from the base plate, where the spacer portion includes a first sub portion and a second sub portion located on the first sub portion and facing the pixel definition portion, the first sub portion and the first segment are formed in a same layer with a same material, and the second sub portion and the second segment are formed in a same layer with a same material.

According to any of the foregoing implementations of the first aspect of the present application, an orthographic projection area of the first sub portion on the base plate is greater than that of the second sub portion on the base plate.

According to any of the foregoing implementations of the first aspect of the present application, an orthographic projection area of the pixel definition portion on the base plate is greater than that of the second sub portion on the base plate.

According to any of the foregoing implementations of the first aspect of the present application, the display panel further includes: light emitting units located in the pixel openings; and a first electrode layer including first electrodes located on sides of the light emitting units away from the base plate, where materials of at least one of the first sub portion and the second sub portion include metal materials, and the first electrodes on two adjacent light emitting units are connected to each other by the spacer portion.

According to any of the foregoing implementations of the first aspect of the present application, the material of the second sub portion includes a metal material, and the material of the first sub portion include an inorganic material.

According to any of the foregoing implementations of the first aspect of the present application, the display panel further includes an encapsulation layer, where the encapsulation layer includes a first inorganic layer, an organic layer located on a side of the first inorganic layer away from the base plate, and a second inorganic layer located on a side of the organic layer away from the first inorganic layer; and the first inorganic layer includes a plurality of independent encapsulating portions, each of which is located in a space enclosed by corresponding isolation portions.

According to any of the foregoing implementations of the first aspect of the present application, the display panel further includes a dam portion, where the dam portion is disposed on the base plate and located in the frame area, the dam portion is disposed surrounding the display area, and the isolation portion is located on a side of the dam portion facing the display area or a side of the dam portion facing away from the display area.

According to any of the foregoing implementations of the first aspect of the present application, the display panel includes two or more dam portions, which are provided and spaced apart in a direction from the display area to the frame area.

According to any of the foregoing implementations of the first aspect of the present application, the display panel includes 2-15 isolation portions, and the 2-15 isolation portions are located at one of following positions: a side of the dam portion facing the display area: a side of the dam portion facing away from the display area; and both of a side of the dam portion facing the display area and a side of the dam portion facing away from the display area.

According to any of the foregoing implementations of the first aspect of the present application, the display panel further includes an encapsulation layer, which includes a first inorganic layer, an organic layer located on a side of the first inorganic layer away from the base plate, and a second inorganic layer located on a side of the organic layer away from the first inorganic layer; and the organic layer is located in a space enclosed by the dam portion.

An embodiment of a second aspect of the present application provides a display apparatus, including the display panel in any of the foregoing implementations.

An embodiment of a third aspect of the present application provides a method for preparing a display panel, where the display panel includes a display area and a frame area surrounding the display area, and the preparing method includes steps of:
disposing a second sub material layer on a base plate;
disposing a first sub material layer on a side of the second sub material layer away from the base plate; and
patterning the first sub material layer and the second sub material layer to form an isolation portion located in the frame area, where a first segment of the isolation portion is formed by the first sub material layer, a second segment of the isolation portion is formed by the second sub material layer, and an orthographic projection area of the first segment on the base plate is greater than that of the second segment on the base plate.

According to implementations of the third aspect of the present application, in the step of patterning the first sub material layer and the second sub material layer to form an isolation portion located in the frame area, where a first segment of the isolation portion is formed by the first sub material layer, a second segment of the isolation portion is formed by the second sub material layer, and an orthographic projection area of the first segment on the base plate is greater than that of the second segment on the base plate:
disposing a photoresist layer on a side of the first sub material layer away from the base plate and forming the first segment by exposure, development and etching; and
continuing to perform side etching on the second sub material layer to form the second segment, so that the orthographic projection area of the second segment on the base plate is less than that of the first segment on the base plate.

According to any of the foregoing implementations of the third aspect of the present application, before the step of disposing a second sub material layer on a base plate, the method further includes:
disposing a pixel definition material layer on the base plate and patterning the pixel definition material layer to form a pixel definition layer, where the pixel definition layer includes a plurality of pixel definition portions located in the display area, a plurality of pixel openings enclosed by the pixel definition portions, and a third segment located on a side of the second segment facing the base plate; and
in the step of disposing a second sub material layer on a base plate, the second sub material layer is disposed on a side of the pixel definition layer away from the base plate.

According to any of the foregoing implementations of the third aspect of the present application, in the step of patterning the first sub material layer and the second sub material layer to form an isolation portion located in the frame area, where a first segment of the isolation portion is formed by the first sub material layer, a second segment of the isolation portion is formed by the second sub material layer, and an orthographic projection area of the first segment on the base plate is greater than that of the second segment on the base plate: further forming a spacer portion located on a side of the pixel definition portion away from the base plate.

### DESCRIPTION OF THE DRAWINGS

Other features, objectives, and advantages of the present application will become more apparent by reading the following detailed descriptions of non-restrictive embodiments with reference to the accompanying drawings, where the same or similar reference numerals indicate the same or similar features, and the accompanying drawings are not drawn to actual scale.

FIG. 1 is a schematic diagram of a display panel in a top view provided in an embodiment of the present application:

FIG. 2 is a cross-sectional view taken along line B-B in FIG. 1:

FIG. 3 is a cross-sectional view taken along line B-B in FIG. 1 in another embodiment:

FIG. 4 is a cross-sectional view taken along line B-B in FIG. 1 in still another embodiment:

FIG. 5 is a schematic flowchart of a method for preparing a display panel provided in an embodiment of the present application:

FIG. 6 is a schematic flowchart of a step in a method for preparing a display panel provided in an embodiment of the present application; and

FIGS. 7 to 15 are schematic diagrams showing a preparing process of a method for preparing a display panel provided in an embodiment of the present application.

### DETAILED DESCRIPTION

Features and exemplary embodiments of various aspects of the present application will be described in detail below. In order to make the objectives, technical solutions, and advantages of the present application clearer, the present application will be further described in detail below with reference to the accompanying drawings and specific embodiments. It should be understood that the specific embodiments described herein are only configured to explain the present application, but not configured to limit the present application. For those skilled in the art, the present application can be implemented without some of these specific details. The following descriptions of the embodiments are merely to provide a better understanding of the present application by showing examples of the present application.

It should be noted that the relational terms herein, such as first and second, are merely used for distinguishing one entity or operation from another, and do not necessarily require or imply that any actual relationship or sequence exists among these entities or operations. Moreover, the terms “include”, “comprise”, and any variants thereof are intended to be a non-exclusive inclusion, so that a process, method, article, or device including or comprising a series of elements not only includes or comprises those elements, but further includes or comprises other elements not listed explicitly, or includes or comprises inherent elements of the process, method, article, or device. In the absence of more limitations, an element defined by “include or comprise a or an . . . ” does not exclude other same elements existing in the process, method, article, or device including or comprising the element.

It should be understood that when the structure of a component is described and when one layer or area is referred to as being located “on” or “above” another layer or area, the one layer or area may be directly located on the another layer or area, or other layers or areas may be included between the one layer or area and the another layer or area. In addition, if the component is turned over, the one layer or area will be located “below” or “under” the another layer or area.

A display panel includes an array base plate, a light emitting device layer disposed on the array base plate, and an encapsulation layer used for encapsulating the light emitting device layer. In related technologies, the light emitting device layer includes a light emitting unit, the light emitting unit includes an organic light emitting material, and the encapsulation layer further includes an organic material. When the encapsulation of the display panel is not tight, water vapor may immerse into the organic material: on the one hand, the water vapor will diffuse into a display area in the organic material and affect the display of the display panel, and on the other hand, the organic material may absorb the water and expand, causing peeling of film layers, which then causes problems such as poor sealing.

To solve the above problems, the embodiments of the present application provide a display panel, a display apparatus, and a method for preparing a display panel. In the display panel provided in the embodiments of the present application, the display panel includes a base plate and an isolation portion disposed on the base plate. The isolation portion includes a first segment and a second segment, so that the isolation portion is relatively high. The second segment is located on a side of the first segment facing the base plate, and an orthographic projection area of the first segment on the base plate is greater than that of the second segment on the base plate. When a functional layer is disposed on the isolation portion, the functional layer will fracture at a position between the first segment and the second segment. Alternatively, the isolation portion is relatively high, making it difficult for a material to be continuous on two sides of the isolation portion, thereby reducing spread of water vapor along the functional layer. The isolation portion is located in the frame area instead of the display area, which can isolate water vapor in the frame area, thereby reducing the impact of the water vapor on organic materials in the display area. Therefore, in the embodiments of the present application, the isolation portion is disposed in the frame area, the isolation portion includes the first segment and the second segment, the isolation portion is relatively high, and the orthographic projection area of the first segment on the base plate is greater than that of the second segment on the base plate: thus, the spread of water vapor to the display area can be reduced and the sealing performance of the display panel can be improved.

Various embodiments of the display panel and the display apparatus will be explained below with reference to the accompanying drawings.

An embodiment of the present application provides a display panel. The display panel may be an organic light emitting diode (OLED) display panel.

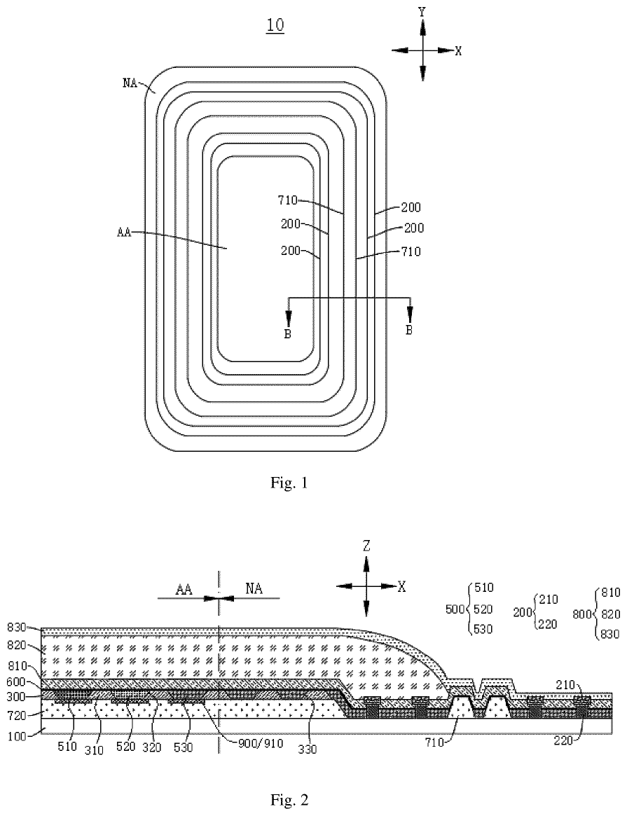

Referring to FIG. 1 to FIG. 3, FIG. 1 is a schematic diagram of a display panel 10 in top view provided according to an embodiment of the present application. FIG. 2 is a cross-sectional view taken along line B-B in FIG. 1.

As shown in FIG. 1 and FIG. 2, a display panel 10 provided in an embodiment of a first aspect of the present application includes a display area AA and a frame area NA surrounding the display area AA, and the display panel 10 includes a base plate 100 and an isolation portion 200; and the isolation portion 200 is disposed on the base plate 100 and located in the frame area NA, the isolation portion 200 includes a first segment 210 and a second segment 220 located on a side of the first segment 210 facing the base plate 100, and an orthographic projection area of the first segment 210 on the base plate 100 is greater than that of the second segment 220 on the base plate 100.

In the display panel 10 provided in the embodiment of the present application, the display panel 10 includes the base plate 100 and the isolation portion 200 disposed on the base plate 100. The isolation portion 200 includes the first segment 210 and the second segment 220, so that the isolation portion 200 is relatively high. The second segment 220 is located on a side of the first segment 210 facing the base plate 100, and the orthographic projection area of the first segment 210 on the base plate 100 is greater than that of the second segment 220 on the base plate 100. In the display panel 10, when a functional layer is disposed on the isolation portion 200, since the orthographic projection area of the first segment 210 on the base plate 100 is greater than that of the second segment 220 on the base plate 100 and the first segment 210 is partially suspended, it is difficult for the functional layer to climb and a fracture of the functional layer may be caused at a position between the first segment 210 and the second segment 220; alternatively, the functional layer is insufficient in thickness to be continuous on two sides of the isolation portion 200, and a fracture of the functional layer also can be caused, thereby reducing spread of water vapor or cracks along the functional layer and improving reliability of encapsulation.

The isolation portion 200 is located in the frame area NA instead of the display area AA, which can isolate water vapor and cracks in the frame area NA, thereby reducing the impact of intrusion of the water vapor on organic materials in the display area AA. Therefore, in the embodiment of the present application, by disposing the isolation portion 200 in the frame area NA, which includes the first segment 210 and the second segment 220, which can reduce the spread of water vapor and cracks to the display area AA and improve the sealing performance of the display panel 10.

The base plate 100 may be provided in many ways, for example, the base plate 100 may be an array base plate, and includes a substrate and a driving circuit layer disposed on the substrate, the driving circuit layer may be located in the display area AA, and the isolation portion 200 may be directly formed on the substrate.

Optionally, the display panel 10 further includes a functional layer, the functional layer is disposed on the base plate 100, the functional layer includes a first portion and a second portion disposed on two sides of the isolation portion 200 in a direction from the display area AA to the frame area NA, and the first portion is located in the display area AA: since the first portion and the second portion are isolated by the isolation portion 200, the spread of water vapor from the second portion to the first portion which affects the performance of the functional layer in the display area AA and the like, can be reduced, and the sealing performance of the display panel 10 can be improved.

Optionally, the functional layer may further include a third portion, the third portion is located on a side of the isolation portion 200 away from the base plate 100, and the third portion is spaced apart from the first portion and the second portion, that is, the third portion is not continuous with the first portion and the second portion, which can reduce the spread of water vapor or cracks from the second segment 220 to the third portion or spread of water vapor from the third portion to the first portion.

Optionally, the display panel 10 further includes a light emitting structural layer, which is disposed on the base plate 100 and located in the display area AA. The light emitting structural layer includes a pixel definition layer 300, the pixel definition layer 300 includes a plurality of pixel definition portions 310 and a plurality of pixel openings 320 enclosed by the pixel definition portions 310, and a light emitting unit 500 is disposed in each pixel opening 320. The display panel 10 further includes an encapsulation layer 800 for encapsulating the light emitting structural layer, and the encapsulation layer 800 may include a first inorganic layer 810, an organic layer 820, and a second inorganic layer 830 sequentially stacked in a direction away from the light emitting structural layer.

Optionally, the above-mentioned functional layer may be a first inorganic layer 810, and the first inorganic layer 810 may fracture at the position of the isolation portion 200, which can reduce the spread of water vapor or cracks along the first inorganic layer 810 to the display area AA and improve the encapsulating reliability of the display panel 10.

In some other embodiments, the functional layer may alternatively be an organic light emitting material layer generated when the light emitting units 500 are prepared, so that at least a portion of the organic light emitting material layer for preparing the light emitting units 500 can fracture at the position of the isolation portion 200, thereby reducing the spread of water vapor along the organic light emitting material layer into the light emitting units 500 and improving the sealing performance of the display panel 10.

The display panel 10 has a length direction Y, a width direction X, and a thickness direction Z. The isolation portion 200 is formed in various shapes, for example, the isolation portion 200 may extend in the length direction Y in a strip shape and be located on a side of the display area AA in the width direction X, or the isolation portion 200 may extend in the width direction X in a strip shape and be located on a side of the display area AA in the length direction Y.

In some other embodiments, with continued reference to FIG. 1, the isolation portion 200 is disposed surrounding the display area AA to form an enclosed construction shaped in a ring.

In these optional embodiments, the isolation portion 200 is disposed in a ring shape, so that the functional layer can fracture at different positions around the display area AA, thereby further reducing the spread of water vapor to the display area AA and improving the sealing performance of the display panel 10.

The number of isolation portions 200 may be various. The number of the isolation portions 200 may be one.

Alternatively, with continued reference to FIG. 1, two or more isolation portions 200 are provided, and the two or more isolation portions 200 are spaced apart from each other in a direction away from the display area AA. By providing a plurality of isolation portions 200, the sealing effect of the display panel 10 can be further improved.

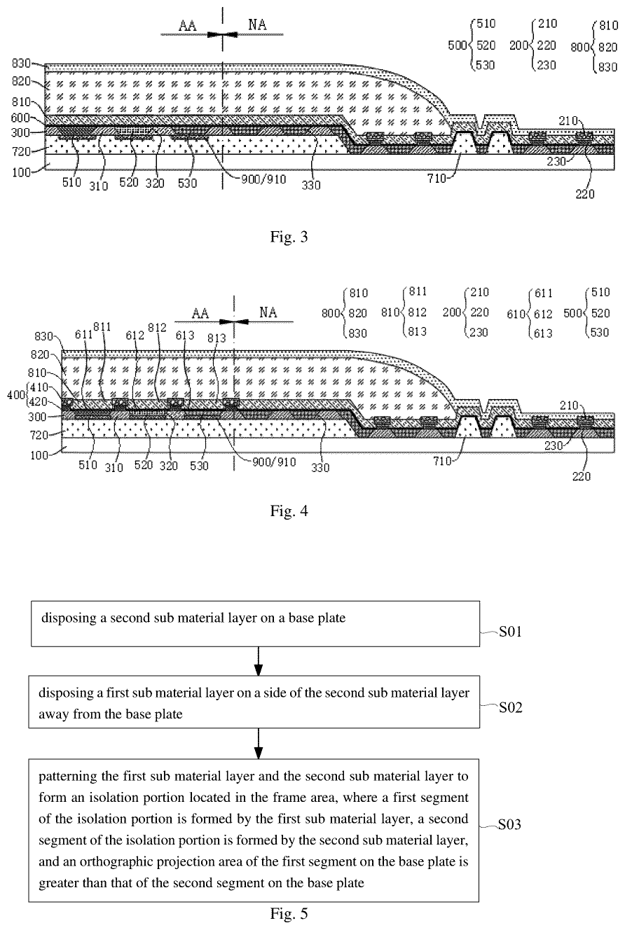

Referring to FIG. 3, FIG. 3 is a cross-sectional view taken along line B-B in FIG. 1 in another embodiment.

In some embodiments, as shown in FIG. 1 and FIG. 3, the isolation portion 200 further includes a third segment 230 located on a side of the second segment 220 facing the base plate 100, and an orthographic projection area of the third segment 230 on the base plate 100 is greater than that of the second segment 220 on the base plate 100.

In these embodiments, the isolation portion 200 is divided into three segments, the second segment 220 is located between the first segment 210 and the third segment 230, and the orthographic projection area of the second segment 220 on the base plate 100 is less than those of the first segment 210 and the third segment 230 on the base plate 100, so that the functional layer is more prone to fracture at the position of the second segment 220.

In some embodiments, as described above, when the display panel 10 includes the above-mentioned pixel definition layer 300, the third segment 230 may be formed in a same layer with a same material as the pixel definition portion 310, so that the third segment 230 and the pixel definition portion 310 can be prepared in a same process step, the preparing process of the display panel 10 can be simplified, and the preparing efficiency of the display panel 10 can be improved.

The pixel definition layer 300 may further include a through hole 330 penetrating through the pixel definition layer, and the through hole 330 is located in the frame area NA. By providing the through hole 330 on the pixel definition layer 300, when water vapor immerses the pixel definition layer 300 or layer structures adjacent to the pixel definition layer 300, the water vapor can be released to the through hole 330, thereby reducing the expansion deformation of the film layer structures and thus mutual separation of film layer structures, due to the intrusion of water vapor in the pixel definition layer 300 or the layer structures adjacent to the pixel definition layer 300.

The through hole 330 is formed in various shapes and the number of the through hole 330 is various. The through hole 330 may be circular, elliptical, polygonal, or in other irregular shapes. The number of the through hole 330 may be one or more. A plurality of through holes 330 may be spaced apart from each other in the frame area NA, or a plurality of through holes 330 may be spaced apart from each other around the display area AA.

Optionally, at least a part of the pixel definition layer 300 located between adjacent two through holes 330 is further used as the third segment 230, to further release, by the through holes 330, the water vapor that is not blocked by the isolation portion 200.

The material of the pixel definition layer 300 may be various. For example, the material of the pixel definition layer 300 includes an inorganic material.

Optionally, the display panel 10 further includes a pixel electrode layer 900, and the pixel electrode layer 900 includes a pixel electrode 910 corresponding to each pixel opening 320, that is, the pixel opening 320 and the light emitting unit 500 located in the pixel opening 320 are correspondingly disposed at a position where the pixel electrode 910 is located. That is, the pixel opening 320 is disposed at the position where the pixel electrode 910 is located and penetrates through the pixel definition layer 300, and the through hole 330 is disposed at a position where the pixel electrode 910 is not located and penetrates through the pixel definition layer 300.

Referring to FIG. 4, FIG. 4 is a cross-sectional view taken along line B-B in FIG. 1 in another embodiment.

In some optional embodiments, as shown in FIG. 1 and FIG. 4, the display panel 10 further includes a spacer portion 400, the spacer portion 400 is located on a side of the pixel definition portion 310 away from the base plate 100, the spacer portion 400 includes a first sub portion 410 and a second sub portion 420 located on the first sub portion 410 and facing the pixel definition portion 310, the first sub portion 410 and the first segment 210 are formed in a same layer with a same material, and the second sub portion 420 and the second segment 220 are formed in a same layer with a same material.

In these optional embodiments, by providing the spacer portion 400 on the pixel definition portion 310 of the pixel definition layer 300, the combined height of the spacer portion 400 and the pixel definition portion 310 is higher. When a light emitting material or another carrier layer is evaporated in the pixel opening 320, these layer structures are prone to fracture at positions of the pixel definition portion 310 and the spacer portion 400, thereby reducing transverse current crosstalk in the carrier layer and improving the display effect of the display panel.

In addition, the first sub portion 410 and the first segment 210 are formed in the same layer with the same material, so that the first sub portion 410 and the first segment 210 can be prepared in the same process step; and the second sub portion 420 and the second segment 220 are formed in the same layer with the same material, so that the second sub portion 420 and the second segment 220 can be prepared in the same process step, which can simplify the preparing process of the display panel 10 and improve the preparing efficiency of the display panel 10.

In some optional embodiments, an orthographic projection area of the first sub portion 410 on the base plate 100 is greater than that of the second sub portion 420 on the base plate 100, that is, a portion of the first sub portion 410 is suspended, and thus, it is difficult for the light emitting material layer and the carrier layer to climb at the suspended position, and fractures may occur at the suspended position, which can block the path between the light emitting material layer and the carrier layer in adjacent sub pixels, thereby further reducing the transverse current crosstalk. For example, the first inorganic layer 810 includes a plurality of independent encapsulating portions, each of which is located in a space enclosed by corresponding spacer portions 400. That is, the first inorganic layer 810 fractures into a plurality of independent encapsulating portions to achieve independent encapsulation of each sub pixel, so that the encapsulating effect of each sub pixel is not affected by that of adjacent sub pixels, which can further reduce the spread of water vapor in the first inorganic layer 810.

In some optional embodiments, an orthographic projection area of the pixel definition portion 310 on the base plate 100 is greater than that of the second sub portion 420 on the base plate 100, so that the functional layer is more prone to fracture at the position of the second sub portion 420.

In some optional embodiments, the display panel 10 further includes a first electrode layer 600, and the first electrode layer 600 includes a first electrode 610 each located on a side of the light emitting unit 500 away from the base plate 100. The first electrode 610 may be an electrode formed in a whole surface, or a plurality of first electrodes 610 may be provided, and each first electrode 610 is located on a side of a corresponding light emitting unit 500 away from the base plate 100.

For example, as mentioned above, the orthographic projection area of the first sub portion 410 on the base plate 100 is greater than that of the second sub portion 420 on the base plate 100, so that a first electrode material layer can be separated by the spacer portions 400 into a plurality of independent first electrodes 610, and the plurality of independent first electrodes 610 can be controlled separately thereby achieving independent control of each first electrode 610.

Optionally, the materials of at least one of the first sub portion 410 and the second sub portion 420 include metal materials. When a plurality of first electrodes 610 are provided, the first electrodes 610 on two adjacent light emitting units 500 may be connected to each other by at least one of the first sub portion 410 and the second sub portion 420, that is, the first electrodes 610 on two adjacent light emitting units 500 may be electrically connected into a surface electrode by the spacer portion 400.

Optionally, the material of the second sub portion 420 includes a metal material, the second sub portion 420 is closer to the pixel definition portion 310, and the second sub portion 420 is closer to the first electrode 610. The material of the second sub portion 420 includes the metal material, which can ensure the stability of electrical connection between the first electrodes 610 on two adjacent light emitting units 500.

Optionally, when the material of the second sub portion 420 includes the metal material, as mentioned above, the material of the second segment 220 is the same as that of the second sub portion 420, so the material of the second segment 220 also includes the metal material.

Optionally, the material of the first sub portion 410 includes an inorganic material, so that the first sub portion 410 has good insulating performance.

In some optional embodiments, the display panel 10 further includes a dam portion 710, the dam portion 710 is disposed on the base plate 100 and located in the frame area NA, the dam portion 710 is disposed surrounding the display area AA, and the isolation portion 200 is located on a side of the dam portion 710 facing the display area AA or a side of the dam portion 710 facing away from the display area AA. Optionally, the organic layer 820 is located in a space enclosed by the dam portion 710. By providing the dam portion 710, the organic layer 820 in the encapsulation layer 800 can be confined inside the dam portion 710. The isolation portion 200 is disposed side by side with the dam portion 710 and located on the side of the dam portion 710 facing the display area AA, or the side of the dam portion 710 facing away from the display area AA, so that the isolation portion 200 and the dam portion 710 will not interfere with each other.

The number of the dam portion 710 is various. There may be one or more dam portions 710. When there are two or more dam portions 710, the two or more dam portions 710 are spaced apart from each other in the direction from the display area AA to the frame area NA.

The number of the isolation portion 200 is various, for example, the display panel 10 may include one isolation portion 200 located on a side of the dam portion 710 facing the display area AA or a side of the dam portion 710 facing away from the display area AA: alternatively, the display panel 10 may include two or more isolation portions 200, for example, 2-15 isolation portions 200 located on a side of the dam portion 710 facing the display area AA, 2-15 isolation portions 200 located on a side of the dam portion 710 facing away from the display area AA, or 2-15 isolation portions 200 located on both of a side of the dam portion 710 facing the display area AA and a side of the dam portion 710 facing away from the display area AA. That is, the isolation portions 200 are disposed on two sides of the dam portion 710, which can further improve the sealing effect of the display panel 10. When the number of isolation portions 200 on the side of the dam portion 710 facing or facing away from the display area AA is within the above range, not only the sealing performance of the display panel 10 can be improved, but also the display effect of the display panel 10 can be prevented from being affected by the large size of the frame area NA due to an excess of isolation portions 200.

Optionally, the array base plate 100 includes a flattening layer 720, and the pixel electrode layer 900 is disposed between the flattening layer 720 and the pixel definition layer 300. At least some dam portions 710 may be formed in a same layer with a same material as the flattening layer 720 to further simplify the preparing process of the display panel 10 and improve the preparing efficiency of the display panel 10.

Optionally, with continued reference to FIG. 4, in any of the above embodiments, the light emitting units 500 include a first light emitting unit 510, a second light emitting unit 520, and a third light emitting unit 530; the pixel openings 320 include a first pixel opening, a second pixel opening, and a third pixel opening; and the first light emitting unit 510 is disposed in the first pixel opening, the second light emitting unit 520 is disposed in the second pixel opening, and the third light emitting unit 530 is disposed in the third pixel opening. In one embodiment of the present application, the first light emitting unit 510, the second light emitting unit 520, and the third light emitting unit 530 are a red light emitting unit, a green light emitting unit, and a blue light emitting unit, respectively, to achieve color display of the display panel 10.

With continued reference to FIG. 4, the first electrodes 610 includes a first sub electrode 611 located on a side of the first light emitting unit 510 away from the base plate 100, a second sub electrode 612 located on a side of the second light emitting unit 520 away from the base plate 100, and a third sub electrode 613 located on a side of the third light emitting unit 530 away from the base plate 100. The first inorganic layer 810 includes a first encapsulating portion 811 located on a side of the first sub electrode 611 away from the base plate 100, a second encapsulating portion 812 located on a side of the second sub electrode 612 away from the base plate 100, and a third encapsulating portion 813 located on a side of the third sub electrode 613 away from the base plate 100.

The display panel 10 may be prepared in various ways. For example, after the flattening layer 720 is prepared, the pixel definition layer 300 is prepared on the flattening layer 720, and the spacer portion 400 and the isolation portion 200 are simultaneously prepared on the pixel definition layer 300.

Then, a first light emitting material layer, a first electrode material layer, and a first encapsulating material layer are successively formed on the base plate 100, and the first light emitting material layer, the first electrode material layer, and the first encapsulating material layer are simultaneously patterned to form the first light emitting unit 510, the first sub electrode 611, and the first encapsulating portion 811. For example, the formation of the first light emitting unit 510, the first sub electrode 611, and the first encapsulating portion 811 by patterning may include etching out the first light emitting material layer, the first electrode material layer, and the first encapsulating material layer located in the second pixel opening and the third pixel opening, and retaining the first light emitting material layer, the first electrode material layer, and the first encapsulating material layer in the first pixel opening to form the first light emitting unit 510, the first sub electrode 611, and the first encapsulating portion 811.

Next, a second light emitting material layer, a second electrode material layer, and a second encapsulating material layer are successively formed on the base plate 100, and the second light emitting material layer, the second electrode material layer, and the second encapsulating material layer are simultaneously patterned to form the second light emitting unit 520, the second sub electrode 612, and the second encapsulating portion 812. For example, the formation of the second light emitting unit 520, the second sub electrode 612, and the second encapsulating portion 812 by patterning may include etching out the second light emitting material layer, the second electrode material layer, and the second encapsulating material layer in the third pixel opening, as well as the second light emitting material layer, the second electrode material layer, and the second encapsulating material layer on a side of the first encapsulating portion away from the base plate, and retaining the second light emitting material layer, the second electrode material layer, and the second encapsulating material layer in the second pixel opening to form the second light emitting unit 520, the second sub electrode 612, and the second encapsulating portion 812.

Finally, a third light emitting material layer, a third electrode material layer, and a third encapsulating material layer are successively formed on the base plate 100: the third light emitting material layer, the third electrode material layer, and the third encapsulating material layer formed on the sides of the first encapsulating portion 811 and the second encapsulating portion 812 away from the base plate are etched off; and the third light emitting material layer, the third electrode material layer, and the third encapsulating material layer formed in the third pixel opening are retained to form the third light emitting unit 530, the third sub electrode 613, and the third encapsulating portion 813. It should be noted that the third light emitting material layer, the third electrode material layer, and the third encapsulating material layer in the frame area NA may not be patterned at this stage, which can simplify the preparing process. Therefore, at least part of the third light emitting material layer, the third electrode material layer, and the third encapsulating material layer fall into the pixel opening 320 to form the third light emitting unit 530, the third sub electrode 613, and the third encapsulating portion 813; and at least part of the third light emitting material layer, the third electrode material layer, and the third encapsulating material layer also fall into the through holes 330 in the frame area NA, fall between adjacent isolation portions 200, between the isolation portion 200 and the dam portion 710, or both of between adjacent isolation portions 200 and between the isolation portion 200 and the dam portion 710, and fall on the dam portion 710.

In the embodiments of the present application, in the presence of the isolation portion 200, the third light emitting material layer, the third electrode material layer, and the third encapsulating material layer are separated from each other at the position of isolation portion 200, thereby reducing the spread of water vapor along the third light emitting material layer, the third electrode material layer, and the third encapsulating material layer.

An embodiment of a second aspect of the present application further provides a display apparatus, including the display panel 10 in any of the above embodiments of the first aspect. Since the display apparatus provided in the embodiments of the second aspect of the present application includes the display panel 10 in any of the above embodiments of the first aspect, the display apparatus provided in the embodiment of the second aspect of the present application has the beneficial effects of the display panel 10 in any of the above embodiments of the first aspect, and details will not be repeated here.

The display apparatus in the embodiment of the present application includes but is not limited to devices with display functions, such as a mobile phone, a personal digital assistant (PDA), a tablet computer, an e-book, a television, an access control, an intelligent fixed-line telephone, and a console.

Referring to FIG. 5, FIG. 5 is a schematic flowchart of a method for preparing a display panel 10 provided in an embodiment of a third aspect of the present application.

An embodiment of a third aspect of the present application further provides a method for preparing a display panel 10. The display panel 10 may be the display panel 10 provided in any of the above embodiments of the first aspect, and the display panel 10 includes a display area AA and a frame area NA surrounding the display area AA. With reference to FIGS. 1 to 4 and 5, the preparing method includes:

Step S01: disposing a second sub material layer on a base plate 100.

Step S02: disposing a first sub material layer on a side of the second sub material layer away from the base plate 100.

Step S03: patterning the first sub material layer and the second sub material layer to form an isolation portion 200 located in the frame area NA, where the first sub material layer forms a first segment 210 of the isolation portion 200, the second sub material layer forms a second segment 220 of the isolation portion 200, and an orthographic projection area of the first segment 210 on the base plate 100 is greater than that of the second segment 220 on the base plate 100.

The display panel 10, prepared by using the embodiment of the present application, includes the base plate 100 and the isolation portion 200 disposed on the base plate 100. The isolation portion 200 includes the first segment 210 and the second segment 220, the second segment 220 is located on a side of the first segment 210 facing the base plate 100, and the orthographic projection area of the first segment 210 on the base plate 100 is greater than that of the second segment 220 on the base plate 100. In the display panel 10, when a functional layer is deposited on the isolation portion 200, the functional layer will fracture at a position between the first segment 210 and the second segment 220, thereby reducing the spread of water vapor along the functional layer. The isolation portion 200 is located in the frame area NA instead of the display area AA, which can isolate water vapor in the frame area NA, thereby reducing the impact of the water vapor on the organic materials in the display area AA. Therefore, by providing the isolation portion 200 in the frame area NA, the embodiments of the present application can reduce the spread of water vapor to the display area AA and improve the sealing performance of the display panel 10.

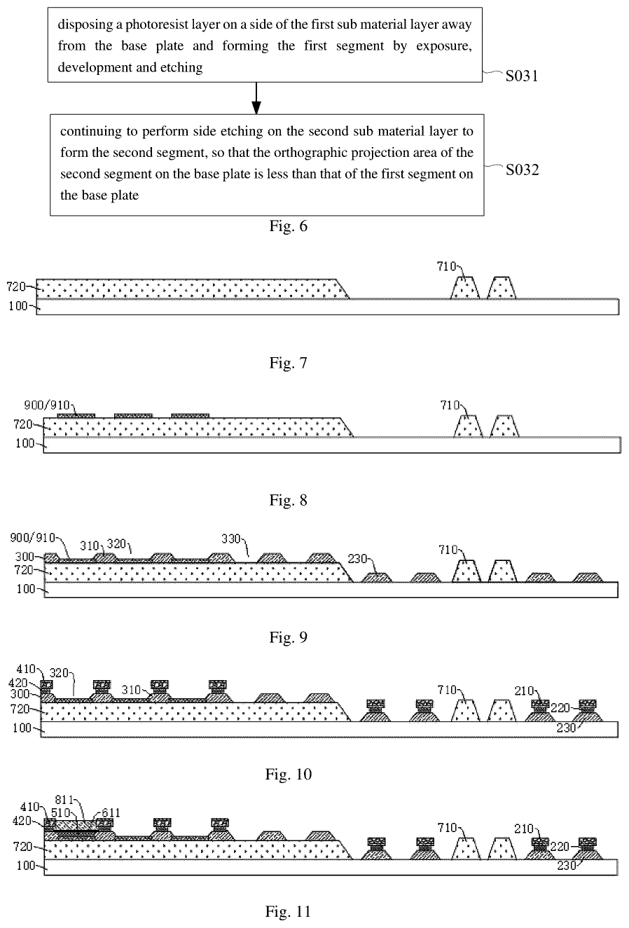

The step S03 is performed in various ways. In some optional embodiments, as shown in FIG. 6, the step S03 includes:

Step S031: disposing a photoresist layer on a side of the first sub material layer 100 away from the base plate 100, and forming the first segment 210 by exposure, development and etching.

Step S032: continuing to perform side etching on the second sub material layer to form the second segment 220, so that the orthographic projection area of the second segment 220 on the base plate 100 is less than that of the first segment 210 on the base plate 100.

In these optional embodiments, after the first sub material layer and the second sub material layer are etched, the side etching is successively performed on the second sub material layer, that is, the second sub material layer located on a side of the first sub portion 410 facing the base plate 100 is etched to form a second sub portion 420 with a size less than that of the first sub portion 410.

In some embodiments, before the step S01, the method further includes: disposing a pixel definition material layer on the base plate 100 and patterning the pixel definition material layer to form a pixel definition layer 300, where the pixel definition layer 300 includes a plurality of pixel definition portions 310 located in the display area AA, a plurality of pixel openings 320 enclosed by the pixel definition portions 310, and a third segment 230 located on a side of the second segment 220 facing the base plate 100.

Then in the step S01, the second sub material layer is disposed on a side of the pixel definition layer 300 away from the base plate 100.

Optionally, in the step 03, a spacer portion 400 located on a side of the pixel definition portion 310 away from the base plate 100 is further formed. The first sub material layer forms the first sub portion 410 of the spacer portion 400, and the second sub material layer forms the second sub portion 420 of the spacer portion 400.

Taking the embodiment of FIG. 4 as an example, the preparing method provided in the embodiments of the present application will be illustrated below with reference to FIGS. 7 to 15. The preparing method for the display panel 10 provided in the embodiments of the present application includes:

Step 1, as shown in FIG. 7, a flattening material layer is disposed on a base plate 100, and the flattening material layer is patterned to form a flattening layer 720 and dam portions 710.

Step 2, as shown in FIG. 8, a pixel electrode layer 900 is prepared on the flattening layer 720, where the pixel electrode layer 900 includes a plurality of pixel electrodes 910 distributed in an array.

Step 3, as shown in FIG. 9, a pixel definition material layer is disposed on the base plate 100 successively, and the pixel definition material layer is patterned to form a plurality of pixel definition portions 310 located in a display area AA and third segments 230 located in a frame area NA.

The third segments 230 determine positions of isolation portions 200, and the third segments 230 may be located on a side of the dam portions 710 facing or facing away from the display area AA. Optionally, in the step 3, through holes 330 located in the frame area NA may be further formed in the pixel definition layer 300.

Step 4, as shown in FIG. 10, a second sub material layer and a first sub material layer are disposed on the base plate 100 successively, and the first sub material layer and the second sub material layer are patterned to form spacer portions 400 located on the pixel definition portions 310 as well as second segments 220 and first segments 210 located on the respective third segments 230.

As mentioned above, the first sub material layer and the second sub material layer may be patterned in two steps. In the first step, a photoresist is first disposed on a side of the first sub material layer away from the second sub material layer, and the side of the first sub material layer away from the second sub material layer is etched forward by means of the photoresist, forming first sub portions 410 and the first segments 210. In the second step, side etching is performed successively on the second sub material layer to form second sub portions 420 and the second segments 220.

Step 5, as shown in FIG. 11, a first light emitting material layer, a first electrode material layer, and a first encapsulating material layer are disposed on the base plate 100 successively; and the first light emitting material layer, the first electrode layer, and the first encapsulating material layer are simultaneously patterned to form a first light emitting unit 510, a first sub electrode 611, and a first encapsulating portion 811.

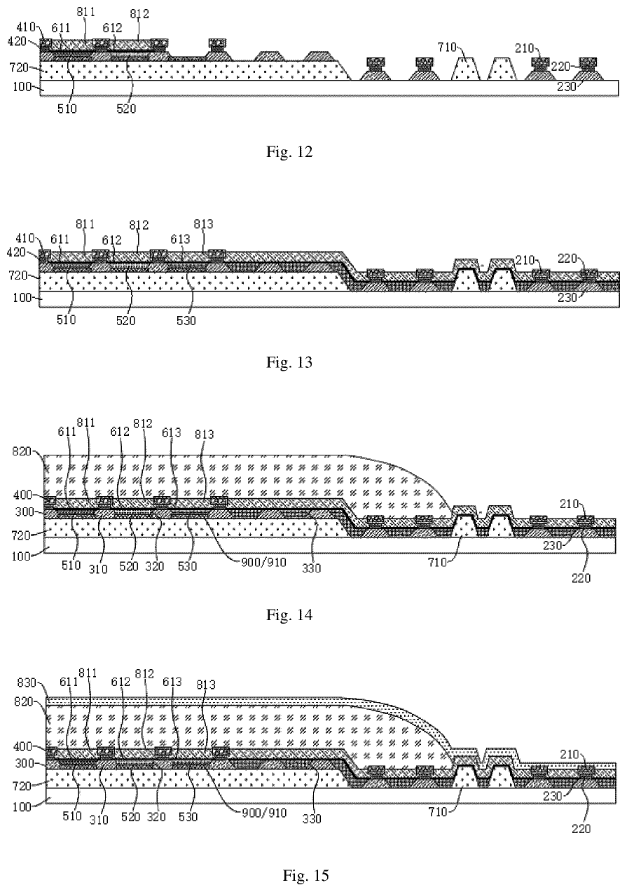

Step 6, as shown in FIG. 12, a second light emitting material layer, a second electrode material layer, and a second encapsulating material layer are disposed on the base plate 100 successively; and the second light emitting material layer, the second electrode layer, and the second encapsulating material layer are simultaneously patterned to form a second light emitting unit 520, a second sub electrode 612, and a second encapsulating portion 812.

Step 7, as shown in FIG. 13, a third light emitting material layer, a third electrode material layer, and a third encapsulating material layer are formed on the base plate 100 and patterned to form a third light emitting unit, a third sub electrode 613, and a third encapsulating portion.

In the step 7, the third light emitting material layer, the third electrode material layer, and the third encapsulating material layer in the frame area NA may not be patterned, which can simplify the preparing process. At least part of the third light emitting material layer, the third electrode material layer, and the third encapsulating material layer fall into a pixel opening 320 to form the third light emitting unit 530, the third sub electrode 613, and the third encapsulating portion 813; and at least part of the third light emitting material layer, the third electrode material layer, and the third encapsulating material layer also fall into the through holes 330 in the frame area NA, fall between adjacent isolation portions 200, between the isolation portions 200 and the dam portions 710, or both of between adjacent the isolation portions 200 and between the isolation portions 200 and the dam portions 710, and fall on the dam portions 710.

Step 8, as shown in FIG. 14, an organic layer 820 is disposed in an area enclosed by the dam portion 710.

Step 9, as shown in FIG. 15, a second inorganic layer 830 is disposed on the base plate 100 successively.

In the embodiments of the present application, in the presence of the isolation portions 200 and the spacer portions 400, the layer such as the third light emitting material layer, the third electrode material layer, and the third encapsulating material layer can be separated at the positions of the isolation portions 200 and the spacer portions 400, thereby reducing the spread of water vapor along the third light emitting material layer, the third electrode material layer, and the third encapsulating material layer.

According to the embodiments described above in the present application, these embodiments do not fully describe all details, and the present application is not limited to the specific embodiments. Apparently, many modifications and changes may be made to the above description. This specification selects and specifically describes these embodiments so as to better explain the principles and practical applications of the present application, so that those skilled in the art can make good use of the present application and modifications based on the present application. The present application is merely limited by the claims and all their scope and equivalents.

What is claimed is:

1. A display panel, comprising a display area and a frame area surrounding the display area, and comprising:
a base plate; and
an isolation portion disposed on the base plate and located in the frame area, wherein the isolation portion comprises a first segment and a second segment located on a side of the first segment facing the base plate, and an orthographic projection area of the first segment on the base plate is greater than that of the second segment on the base plate.

2. The display panel according to claim 1, wherein the isolation portion is disposed surrounding the display area to form an enclosed construction shaped in a ring.

3. The display panel according to claim 1, wherein the isolation portion further comprises a third segment located on a side of the second segment facing the base plate, and an orthographic projection area of the third segment on the base plate is greater than that of the second segment on the base plate.

4. The display panel according to claim 3, further comprising:
a pixel definition layer disposed on the base plate, wherein the pixel definition layer comprises a plurality of pixel definition portions located in the display area and a plurality of pixel openings enclosed by the pixel definition portions, and the third segment and the pixel definition portions are formed in a same layer with a same material.

5. The display panel according to claim 4, wherein the pixel definition layer further comprises through holes penetrating through the pixel definition layer, and the through holes are located in the frame area.

6. The display panel according to claim 5, wherein at least a part of the pixel definition layer located between adjacent two through holes is further used as the third segment.

7. The display panel according to claim 4, further comprising:
a spacer portion located on a side of the pixel definition portion away from the base plate, wherein the spacer portion comprises a first sub portion and a second sub portion located on the first sub portion and facing the pixel definition portion, the first sub portion and the first segment are formed in a same layer with a same material, and the second sub portion and the second segment are formed in a same layer with a same material.

8. The display panel according to claim 7, wherein an orthographic projection area of the first sub portion on the base plate is greater than that of the second sub portion on the base plate.

9. The display panel according to claim 7, wherein an orthographic projection area of the pixel definition portion on the base plate is greater than that of the second sub portion on the base plate.

10. The display panel according to claim 7, further comprising:
light emitting units located in the pixel openings; and
a first electrode layer comprising first electrodes located on sides of the light emitting units away from the base plate,
wherein materials of at least one of the first sub portion and the second sub portion comprise metal materials, and the first electrodes on two adjacent light emitting units are connected to each other by the spacer portion.

11. The display panel according to claim 7, wherein the material of the second sub portion comprises a metal material, and the material of the first sub portion comprises an inorganic material.

12. The display panel according to claim 7, further comprising an encapsulation layer, wherein the encapsulation layer comprises a first inorganic layer, an organic layer located on a side of the first inorganic layer away from the base plate, and a second inorganic layer located on a side of the organic layer away from the first inorganic layer, the first inorganic layer comprises a plurality of independent encapsulating portions, each encapsulating portion is located in a space enclosed by corresponding isolation portions.

13. The display panel according to claim 1, further comprising a dam portion, wherein the dam portion is disposed on the base plate and located in the frame area, the dam portion is disposed surrounding the display area, and the isolation portion is located on a side of the dam portion facing the display area or a side of the dam portion facing away from the display area.

14. The display panel according to claim 13, comprising at least two dam portions spaced apart from each other in a direction from the display area to the frame area.

15. The display panel according to claim 13, comprising 2-15 isolation portions, and the 2-15 isolation portions are located at one of following positions: a side of the dam portion facing the display area, a side of the dam portion facing away from the display area, and both of a side of the dam portion facing the display area and a side of the dam portion facing away from the display area.

16. A display apparatus, comprising the display panel according to claim 1.
